(19) United States
(12) Patent Application Publication
(10) Pub. No.: US 2016/0280991 A1
(43) Pub. Date: Sep. 29, 2016

(54) PROCESS FOR INCREASING THE PHOTOLUMINESCENCE INTERNAL QUANTUM EFFICIENCY OF NANOCRYSTALS, IN PARTICULAR OF AGINS2-ZNS NANOCRYSTALS

(71) Applicant: COMMISSARIAT À L'ENERGIE ATOMIQUE ET AUX ENERGIES ALTERNATIVES, Paris (FR)

(72) Inventors: Théo CHEVALLIER, Grenoble (FR); Frédéric CHANDEZON, Moirans (FR); Gilles LE BLEVENNEC, Bernin (FR)

(73) Assignee: COMMISSARIAT À L'ENERGIE ATOMIQUE ET AUX ENERGIES ALTERNATIVES, Paris (FR)

(21) Appl. No.: 15/078,546

(22) Filed: Mar. 23, 2016

(30) Foreign Application Priority Data
Mar. 23, 2015 (FR) 15 52400

(51) Int. Cl. C09K 11/62; H01L 33/50

(52) U.S. Cl. CPC C09K 11/623; H01L 33/502

(57) ABSTRACT

The photoluminescence internal quantum efficiency of nanoparticles formed in all or part of a nanocrystal of AgₓM_{y}M′_{z}S_{0.5x+y+1.5z} (I) type, including at least the stages in: (1) having available nanoparticles formed in all or part of a nanocrystal, the chemical composition of which corresponds to the formula (I): AgₓM_{y}M′_{z}S_{0.5x+y+1.5z} (I); the nanoparticles being functionalized at the surface by an organic ligand L1 different from a ligand of phosphine type; wherein the nanocrystals having the chemical composition of formula (I) are prepared beforehand via a process employing only a single stage of heat treatment; and (2) bringing together the nanoparticles and at least one ligand compound L2 of phosphine type of general formula PR₃ (II), or its oxidized form O═PR₃ (II′), under conditions favorable to an exchange, at least in part, of the organic ligands L1 by said ligands of phosphine type L2.

The present invention is targeted at providing a novel method which makes it possible to increase the photoluminescence efficiency of semiconductor particles based on nanocrystals such as those formed of solid solutions of AgInS₂—ZnS type (better known under the term “ZAIS”).

Generally, photoluminescence consists of converting the photons of a certain wavelength into photons of a different wavelength, generally of lower energy. In a first step, the excitation photons are absorbed by the material. In a second step, the energy absorbed may be partly restored in the form of photons having a wavelength corresponding to the difference in energy of the electron levels involved during the de-excitation of the material. The losses occasioned during this process are related to the “nonradiative” phenomena of recombination of the carriers, generally facilitated by the presence of defects in the material.

The internal quantum efficiency (IQE) is the absolute measurement of the ratio of the total number of photons emitted by the material to the total number of photons absorbed. An IQE of 100% thus indicates that each photon absorbed has given rise to an emitted photon, without losses caused by nonradiative phenomena. The IQE is thus a universal measurement of the efficiency of the process of luminescence of a material, whatever its type (molecule, semiconductor particle, oxide doped with rare earth metals, and the like).

However, the overall efficiency of a luminescent material is also related to its ability to absorb the exciting light. The materials used commercially in the field of white light-emitting diodes (LEDs) are oxides doped with rare earth metals, typically YAG:Ce (acronym for “Yttrium Aluminum Garnet” doped with cerium (Ce)), which exhibit very good internal quantum efficiencies but poor absorptions.

On the other hand, semiconductor nanocrystals exhibit an absorption by weight which is approximately 1000 times greater but poorer internal quantum efficiencies.

The present invention is targeted precisely at increasing the photoluminescence quantum efficiency of semiconductor nanocrystals having the chemical composition AgₓM_{y}M′_{z}S_{0.5x+y+1.5z} (with M representing Zn, Cd, Hg or their mixtures; M′ representing Al, Ga, In, Tl or their mixtures, and 0<x≦1, 0≦y≦1 and 0<z≦1), such as, for example, nanocrystals formed of solid solutions of AgₓZn_{y}In_{z}S_{0.5x+y+1.5z} type (more generally known as “AgInS₂—ZnS solid solutions” or more simply “ZAIS”), in order to benefit from the strong intrinsic absorption of these materials.

Nanocrystals of ZAIS type are known for their property of photoluminescence within a broad range of the spectrum of visible light, depending on their chemical composition. The synthesis by the liquid route and the use of ZAIS nanocrystals have already been developed by Torimito et al. ([1]) and Park Joung et al. ([2], [3]). The structure of these materials is that of a solid solution similar to the cubic phase of ZnS, the zinc sites of which are randomly occupied by silver, indium or zinc, in variable proportions. The exact composition of the material determines the energy levels involved and thus the photoluminescence which results therefrom, and also the quantum efficiency which is associated with it. These materials exhibit a broad emission band (approximately 150 nm) and may be used as markers in biology or as emitting materials in a light-emitting diode. In particular, the emission width, the strong absorption, the low cost and the nontoxicity of ZAIS nanocrystals make them a material of choice for an application as luminophore in a white LED.

The proposal has already been made, in order to increase the quantum efficiency of these materials, to employ an additional annealing stage and to form a protecting ZnS shell at the surface of the nanocrystals ([4]). Improved quantum efficiencies, ranging from 20% (green) to 80% (red), may thus be obtained with ZAIS nanocrystals coated with a ZnS shell, whereas quantum efficiencies for shell-free nanocrystals range from 15% (green) to 66% (red).

The present invention is targeted at providing a novel process which makes it possible to further increase the photoluminescence internal quantum efficiency (IQE) of nanocrystals having a chemical composition of AgₓM_{y}M′_{z}S_{0.5x+y+1.5z} type and in particular ZAIS nanocrystals, in particular for the purpose of their use as luminophore in a white light-emitting diode.

Thus, according to a first of its aspects, the present invention relates to a process for increasing the photoluminescence internal quantum efficiency of nanoparticles formed at least partly of a nanocrystal of AgₓM_{y}M′_{z}S_{0.5x+y+1.5z} type, comprising at least the stages consisting in:

(1) having available nanoparticles formed in all or part of a nanocrystal, the chemical composition of which corresponds to the formula (I):

AgₓM_{y}M′_{z}S_{0.5x+y+1.5z} (I)

in which:

M is chosen from zinc, cadmium, mercury and their mixtures;

M′ is chosen from aluminum, gallium, indium, thallium and their mixtures;

0<x≦1, 0≦y≦1 and 0<z≦1;

said nanoparticles being functionalized at the surface by at least one organic ligand L1 different from a ligand of phosphine type; and

(2) bringing together said nanoparticles and at least one ligand compound L2 of phosphine type of general formula:

PR₃ (II), or its oxidized form O═PR₃ (II′),

each of the R groups, which are identical or different, being chosen from hydrogen, an alkyl group and a cycloalkyl group, said alkyl and cycloalkyl groups optionally being substituted;

under conditions favorable to an exchange, at least in part, of the organic ligands L1 by said ligands of phosphine type L2.

In the continuation of the text, the term “nanocrystals having the composition (I)” will more simply denote the nanocrystals, the chemical composition of which corresponds to the abovementioned formula (I).

According to an alternative embodiment, the nanoparticles considered according to the invention are formed in all or part of a nanocrystal composed of a solid solution of AgInS₂—ZnS type, denoted in the continuation of the text “ZAIS nanocrystal”. In other words, in the context of this alternative form, the chemical composition of the nanocrystal corresponds to the abovementioned formula (I) in which M represents zinc, M′ represents indium and 0<x, y, z≦1.

The inventors have thus discovered that it is possible to significantly increase the photoluminescence internal quantum efficiency (IQE) of the semiconductor nanocrystals having the composition (I) considered according to the invention, such as ZAIS nanocrystals, by functionalizing them with specific ligands of phosphine type, such as trioctylphosphine (TOP).

The use of trioctylphosphine (TOP) or of trioctylphosphine oxide (TOPO) for semiconductor nanocrystals is standard in the field of the synthesis of quantum dots. These ligands are used therein with the aim of controlling the size of the crystallites synthesized. In fact, in the case where the semiconductor particle reaches a sufficiently small size, the phenomenon of quantum confinement has the effect of increasing the difference in energy between the levels which produce the luminescence and thus of modifying the wavelength emitted. On the other hand, quantum confinement has no effect on the luminescence quantum efficiency. Furthermore, generally, the size of the ZAIS nanocrystals is greater than the critical size below which the phenomenon of quantum confinement comes into play. Consequently, trioctylphosphine and its oxide are not generally used as ligands for the synthesis of nanocrystals of ZAIS type.

It may be noted that Mao et al. [5] employ TOP during the synthesis of ZAIS nanocrystals. However, no information is given with regard to the surface state of the nanocrystals resulting from the synthesis described, which furthermore results in low quantum efficiencies.

Finally, in the context of the use of ligands for the surface functionalization of semiconductor nanocrystals, it has been shown that an exchange of the phosphine ligands by amine ligands at the surface of CdSe-based quantum dots makes it possible to intensify the emission originating from the defects intrinsically present in the structure ([6]).

However, to the knowledge of the inventors, the use of ligands of phosphine type has never been proposed for increasing the photoluminescence internal quantum efficiency of the nanocrystals having the composition (I) which are considered according to the invention, in particular of the nanocrystals which are prepared according to the novel process as detailed below, especially ZAIS nanocrystals.

The implementation of the process for the functionalization of nanocrystals according to the invention, for example ZAIS nanocrystals, proves to be particularly advantageous, in particular for their use as luminophore in a white light-emitting diode.

As illustrated in the examples which follow, the functionalization of the nanocrystals having the composition (I) according to the invention, like ZAIS nanocrystals, by a ligand of phosphine type according to the invention, for example trioctylphosphine, makes it possible to attain significantly improved quantum efficiencies.

The invention thus relates, according to another of its aspects, to the use of a compound of phosphine type of formula PR₃ (II) or its oxidized form O═PR₃ (II′), R being as defined above, as ligand for the functionalization of nanoparticles formed in all or part of a nanocrystal, the chemical composition of which corresponds to the abovementioned formula (I), in order to improve their photoluminescence internal quantum efficiency.

Advantageously, the improvement in the photoluminescence performance of the nanoparticles functionalized at the surface according to the invention appears whatever the solvent (chloroform or toluene, for example) or the polymer (polymethacrylate (PMMA) or polystyrene, for example) in which the functionalized nanoparticles are dispersed.

Furthermore, as described in detail in the continuation of the text, this surface functionalization of the nanoparticles according to the invention may be combined with the use of a ZnS shell, thus making it possible to attain optimized photoluminescence quantum efficiencies.

Finally, the inventors have developed a novel process for the synthesis of the nanocrystals having the composition (I) which are considered according to the invention, for example ZAIS nanocrystals, employing a single stage of heating the precursor dispersed in the organic ligand L1 (for example an amine, such as oleylamine) and making it possible, surprisingly, to further increase the photoluminescence quantum efficiency of the functionalized nanoparticles according to the invention.

Thus, according to a specific embodiment, the invention relates to a process for increasing the photoluminescence internal quantum efficiency of nanoparticles formed at least partly of a nanocrystal of AgₓM_{y}M′_{z}S_{0.5x+y+1.5z} type, comprising at least the stages consisting in:

(1) having available nanoparticles formed in all or part of a nanocrystal, the chemical composition of which corresponds to the formula (I):

AgₓM_{y}M′_{z}S_{0.5x+y+1.5z} (I)

in which

M is chosen from zinc, cadmium, mercury and their mixtures;

M′ is chosen from aluminum, gallium, indium, thallium and their mixtures;

0<x≦1, 0≦y≦1 and 0<z≦1;

said nanoparticles being functionalized at the surface by at least one organic ligand L1 different from a ligand of phosphine type;

wherein the nanocrystals having the chemical composition of formula (I) are prepared beforehand via a process comprising at least the stages consisting in:
(a) having available a precursor powder having the composition AgₓM_{y}M′_{z}(S₂CN(C₂H₅)₂)_{x+2y+3z}, with M, M′, x, y and z being as defined above;
(b) dispersing said precursor powder in the organic ligand L1 in the liquid state; and
(c) subjecting the dispersion obtained in stage (b) to a heat treatment, under an inert atmosphere, at a temperature of between 100° C. and 250° C., to obtain said nanocrystals having the composition (I);
said process for the preparation of the nanocrystals having the composition (I) employing only a single stage of heat treatment consisting in stage (c);
and

(2) bringing together said nanoparticles and at least one ligand compound L2 of phosphine type of general formula:

PR₃ (II), or its oxidized form O═PR₃ (II′),

each of the R groups, which are identical or different, being chosen from hydrogen, an alkyl group and a cycloalkyl group, said alkyl and cycloalkyl groups optionally being substituted;

under conditions favorable to an exchange, at least in part, of the organic ligands L1 by said ligands of phosphine type L2.

Besides its influence on the luminescence quantum efficiency, the modified process for the synthesis of the nanocrystals which are considered according to the invention, in comparison with the synthesis protocol provided by Torimoto et al. [1], brings about a shift in the emission by the nanocrystals towards lower wavelengths (blue-shift effect), which is particularly advantageous in the case of the application of the nanoparticles according to the invention as the luminophore material in a white light-emitting diode (LED) for efficiently converting the blue light into yellow light.

Other characteristics, alternative forms and advantages of the process according to the invention, and of its implementation, will be brought out better on reading the description, examples and figures which follow, given by way of illustration and without limitation of the invention.

In the continuation of the text, the expressions “of between . . . and . . . ”, “ranging from . . . to . . . ” and “varying from . . . to . . . ” are equivalent and are understood to mean that the limits are included, unless otherwise mentioned.

Unless otherwise indicated, the expression “comprising a(n)” should be understood as “comprising at least one”.

Stage (1): Nanoparticles Functionalized by an Organic Ligand L1

As specified above, stage (1) of the process of the invention consists in having available nanoparticles formed in all or part of a nanocrystal which is prepared according to the novel process as detailed below and has the chemical composition corresponding to the formula (I):

AgₓM_{y}M′_{z}S_{0.5x+y+1.5z} (I)

in which:

M is chosen from zinc (Zn), cadmium (Cd), mercury (Hg) and their mixtures;

M′ is chosen from aluminum (Al), gallium (Ga), indium (In), thallium (Tl) and their mixtures;

0<x≦1, 0≦y≦1 and 0<z≦1;

said nanoparticles being functionalized at the surface by at least one organic ligand, denoted L1 in the continuation of the text, different from a ligand of phosphine type.

Nanoparticles

According to a specific embodiment, M in the abovementioned formula (I) represents zinc.

According to another specific embodiment, M′ in the abovementioned formula (I) represents indium.

According to an alternative embodiment, the nanoparticles employed according to the invention are formed at least in part of a nanocrystal, the chemical composition of which corresponds to the abovementioned formula (I) in which M represents Zn and M′ represents indium.

In other words, the nanocrystal may have the following composition (I′):

AgₓZn_{y}In_{z}S_{0.5x+y+1.5z} (I′)

with x, y and z being as defined above.

In another alternative embodiment, M and M′, in the abovementioned formula (I), may comprise atoms different respectively from zinc and indium. The atoms or mixtures of atoms M and M′ are advantageously chosen in order to have a mean ionic radius similar to that of zinc and indium respectively. The stability of the crystal structure may be more assured in proportion by its ability to adjust, in particular by creating defects in the crystal lattice.

According to a specific embodiment, y in the abovementioned formula (I) or (I′) has the value 0. By way of example, an AgInS₂ nanocrystal may be concerned.

According to another specific embodiment, y in the abovementioned formula (I) or (I′) is different from 0.

In particular, according to one alternative embodiment, the nanocrystal considered according to the invention is composed of a solid solution of AgₓZn_{y}In_{z}S_{0.5x+y+1.5z} (I′) type in which x, y and z vary between 0 and 1, x, y and z all being different from zero.

These solid solutions are more generally referred to as “AgInS₂—ZnS solid solutions” and are known under the abbreviation “ZAIS”.

In the context of this alternative embodiment, x, y and z may be such that: x=z and y=2-2x.

Still in the context of this alternative embodiment, x may more particularly vary between 0.4 and 1; y may more particularly vary between 0.1 and 1.2; and z may more particularly vary between 0.4 and 1.

Several alternative forms of nanoparticles may be envisaged. The nanoparticles may be formed of said nanocrystal or exhibit a core/shell structure, the core being composed of said nanocrystal. In all cases, said nanocrystal is prepared according to the novel process as detailed below which employs a single stage of heat treatment performed on the dispersion of the precursor in the organic ligand L1.

According to a first alternative embodiment, nanoparticles are formed of the nanocrystal having the composition (I) as defined above. By way of example, the nanoparticles may be ZAIS nanocrystals.

The nanocrystals considered according to the invention, for example the ZAIS nanocrystals, may exhibit a mean size of greater than or equal to 3 nm, in particular of between 3 nm and 12 nm and more particularly of between 5 nm and 8 nm.

The mean size of the nanocrystals may be determined by electron microscopy, in particular by transmission electron microscopy and more particularly by high resolution transmission electron microscopy (HRTEM) or scanning transmission electron microscopy (STEM).

For such sizes of nanocrystals (≧3 nm), the phenomenon of quantum confinement, for example known for semiconductor nanocrystals of quantum dot type, does not take place.

According to a second alternative embodiment, the nanoparticles may exhibit a structure of core/shell type, the core being formed of a nanocrystal having the composition (I) as described above, for example of a ZAIS nanocrystal, and the shell being made of a semiconductor compound.

The semiconductor compound is more particularly a binary, ternary or quaternary semiconductor alloy formed of at least one element from Group I, II or III (element from Columns I, II or III of the Periodic Table of the Elements) and of at least one element from Group V or VI (element from Columns V or VI of the Periodic Table of the Elements).

It may, for example, be a semiconductor alloy chosen from ZnS, ZnSe, CdS, AlP, GaP, Al₂S₃ and Ga₂S₃. In particular, the semiconductor compound can be ZnS.

According to a specific embodiment, the nanoparticles exhibit a core composed of a ZAIS nanocrystal covered with a ZnS shell.

The nanoparticles having a core/shell structure may exhibit a mean size of between 3 and 40 nm, in particular between 5 and 10 nm.

The shell of the nanoparticles, in particular made of ZnS, may exhibit a thickness of between 0.5 and 15 nm, in particular between 1 and 3 nm.

Organic Ligand L1 for Functionalization of the Nanoparticles

The nanoparticles employed in stage (1) of the process according to the invention are functionalized at the surface by at least one organic ligand different from the ligands of phosphine type.

The organic ligands L1 may be of varied nature. They are advantageously chosen from the compounds exhibiting a boiling point sufficiently high in order to be able to act as solvent for the synthesis of the nanoparticles, as described in detail in the continuation of the text.

In particular, the ligand compound L1 may advantageously exhibit a boiling point of greater than or equal to 180° C., in particular of greater than or equal to 250° C. and more particularly of greater than or equal to 365° C.

The organic ligands L1 may, for example, be chosen from:
amines comprising at least one saturated or unsaturated and linear or branched hydrocarbon chain comprising at least 8 carbon atoms;
alkenes comprising at least 10 carbon atoms, such as, for example, octadecene; and
thiols comprising at least one saturated or unsaturated and linear or branched hydrocarbon chain comprising at least two carbon atoms, such as, for example, dodecanethiol.

According to an alternative embodiment, the ligand L1 is chosen from amines, in particular amines exhibiting a saturated or unsaturated and linear or branched hydrocarbon chain comprising from 8 to 30 carbon atoms.

In particular, it may be a primary amine.

According to a particularly preferred embodiment, the functionalization ligand is oleylamine.

Preparation of the Nanoparticles

As mentioned above, the nanocrystals considered in stage 1) according to the invention, such as ZAIS nanocrystals, are prepared beforehand via a novel process comprising at least the stages consisting in:

(a) having available a precursor powder having the composition AgₓM_{y}M′_{z}(S₂CN(C₂H₅)₂)_{x+2y+3z}, with M, M′, x, y and z being as defined above;

(b) dispersing said precursor powder in the organic ligand L1 in the liquid state; and

(c) subjecting the dispersion obtained in stage (b) to a heat treatment, under an inert atmosphere, for example under an argon atmosphere, at a temperature of between 100° C. and 250° C., to obtain said nanocrystals having the composition (I).

The process for the preparation of the nanocrystals having the composition (I) thus employs a single stage of heat treatment consisting in stage (c).

In other words, the process for the preparation of the nanocrystals having the composition (I) employs a single heat treatment stage performed on the dispersion of said precursor in the organic ligand L1 according to stage (c).

This means that stages (a) and (b) do not include any heating of the precursor. In particular, stages (a) and (b) are performed at room temperature.

Thus, in the process for the preparation of the nanocrystals having the composition (I) according to the invention, the precursor is not pre-heated before the addition of the organic ligand L1.

According to a particular embodiment, the process for the preparation of the nanocrystals having the composition (I) consists in stages (a) to (c), stage (c) being the single heat treatment stage of said process.

Surprisingly, the inventors have shown that the preparation of the nanocrystals having the composition (I), for example ZAIS nanocrystals, according to the modified process described above, employing only a single stage of heating the precursor dispersed in the organic ligand L1, for example in an amine, such as oleylamine, makes it possible, in comparison with the known synthesis of the publication [1], to shift the photoluminescence emission of the nanocrystals towards smaller wavelengths.

This effect is observed whatever the surface functionalization of the nanocrystals (organic ligands L1, for example of amine type, or ligands of phosphine type according to the invention).

Furthermore, the preparation of the nanocrystals according to the process of the invention renders superfluous the implementation of an additional annealing stage, as provided by Torimoto et al. ([4]).

Thus, the invention relates, generally, to a novel process for the preparation of nanocrystals, the chemical composition of which corresponds to the abovementioned formula (I), comprising at least the stages consisting in:
having available a precursor powder having the composition AgₓM_{y}M′_{z}(S₂CN(C₂H₅)₂)_{x+2y+3z}, with M, M′, x, y and z being as defined above;
dispersing said precursor powder in an organic ligand L1, in particular an amine, such as oleylamine, in the liquid state;
subjecting the dispersion to a heat treatment, under an inert atmosphere, at a temperature of between 100° C. and 250° C.; and optionally
recovering the nanocrystals having the chemical composition of the abovementioned formula (I), functionalized at the surface by the organic ligand L1, formed on conclusion of the heat treatment stage.

Furthermore, unexpectedly, as illustrated in example 5, the preparation of the nanocrystals considered according to the invention, in particular of the ZAIS nanocrystals, according to this novel process makes it possible to intensify the increase in the photoluminescence internal quantum efficiency obtained with a functionalization according to the invention of the nanoparticles by specific ligands of phosphine type.

According to a specific embodiment, the precursor powder employed has the composition AgₓM_{y}M′_{z}(S₂CN(C₂H₅)₂)_{x+2y+3z} with x=z and y=2-2x, for example x and z having a value of approximately 0.9 and y having a value of approximately 0.2, or with x and z having a value of approximately 0.7 and y having a value of approximately 0.6.

In particular, in the context of the preparation of ZAIS nanocrystals, the precursor powder employed may have the composition AgₓZn_{y}In_{z}(S₂CN(C₂H₅)₂)_{x+2y+3z}, with x=z and y=2-2x, for example x and z having a value of approximately 0.9 and y having a value of approximately 0.2.

The ZAIS nanocrystals prepared from such a precursor composition exhibit an optimum photoluminescence quantum efficiency.

The precursor powder having the composition AgₓM_{y}M′_{z}(S₂CN(C₂H₅)₂)_{x+2y+3z} may be prepared beforehand, as illustrated in example 1, by precipitation in an aqueous medium of sodium diethyldithiocarbamate with the metal ions in the form of nitrates AgNO₃, In(NO₃)₃ and Zn(NO₃)₂ in appropriate proportions.

The ligand compound L1, for example of amine type, intended to form the ligands at the surface of the ZAIS nanocrystals, employed in the liquid state in stage (b) is used as solvent for the synthesis of the nanocrystals.

According to a specific embodiment, the organic ligand L1 is oleylamine.

According to a specific embodiment, the heat treatment in stage (c) is carried out at a temperature of approximately 180° C.

The duration of the heating may be of between 3 minutes and 4 hours, in particular between 5 minutes and 1 hour and more particularly between 10 and 30 minutes. Preferably, it is of between 20 and 30 minutes.

The heat treatment may, for example, be carried out under an argon atmosphere.

The nanoparticles are prepared from the nanocrystals having the composition (I) formed on conclusion of the heat treatment of stage (c).

More particularly, nanocrystals having the composition (I) and functionalized at the surface by the organic ligand L1 may be recovered directly after stage (c) or they may be submitted to one ore more subsequent stages aimed at forming nanoparticles with a core/shell structure.

As touched on above, according to an alternative embodiment, the nanoparticles considered according to the invention are formed of a nanocrystal having the composition (I), for example of a ZAIS nanocrystal.

The nanocrystals functionalized at the surface by the organic ligand L1, for example by an amine, such as oleylamine, may be recovered in a subsequent stage (d) of the synthesis process described above by centrifuging the reaction medium obtained on conclusion of the heat treatment of stage (c) and precipitating the nanocrystals, for example using methanol.

These nanocrystals may be redispersed in chloroform in order to form a stable colloidal suspension.

According to another alternative embodiment touched on above, the nanoparticles may exhibit a structure of core/shell type, the core being formed of a nanocrystal having the composition (I) and the shell being made of a semiconductor compound.

Such nanoparticles having a core/shell structure may be obtained by forming, at the surface of the nanocrystals having the composition (I), for example ZAIS nanocrystals, prepared as described above, a shell made of semiconductor, for example made of ZnS.

The nanoparticles having a core/shell structure, the core being formed of a nanocrystal having the composition (I) and the shell made of a conducting alloy, may more particularly be prepared via at least the stages consisting in:

(i) having available nanocrystals having the composition (I), for example ZAIS nanocrystals, dispersed in the organic ligand L1, in particular an amine, such as oleylamine, in the liquid state;

(ii) adding, to said dispersion of nanocrystals, at least one precursor of the element or elements from Group I, II or III and at least one precursor of the element or elements from Group V or VI;

(iii) subjecting the dispersion thus formed to a heat treatment favorable to the formation of a coating of semiconductor compound at the surface of the nanocrystals; and

(iv) recovering the nanoparticles having a core/shell structure which are functionalized at the surface by said organic ligand L1.

The dispersion of nanocrystals having the composition (I), for example ZAIS nanocrystals, in stage (i) is more particularly obtained on conclusion of stage (c) of the process for the preparation of the nanocrystals described above.

The precursors of the element or elements from Group I, II or III and of the element or elements from Group V or VI are appropriately chosen from the viewpoint of the nature of the desired shell made of semiconductor.

By way of example, for the formation of a shell made of ZnS, the dispersion of the nanocrystals may be supplemented in stage (ii) with zinc acetate and thioacetamide.

The heat treatment for forming the coating made of semiconductor compound, in particular made of ZnS, may be carried out, under an inert atmosphere, for example of nitrogen or of argon, at a temperature of between 100 and 250° C., in particular between 130 and 180° C.

The duration of the heat treatment may, for example, be of between 1 and 30 minutes.

As described above, the nanoparticles having a core/shell structure which are functionalized at the surface by the organic ligand L1, for example by an amine, such as oleylamine, may be recovered in stage (iv) by precipitation from methanol.

These nanoparticles may be redispersed in chloroform in order to form a stable colloidal suspension.

Thus, according to a particular embodiment, the nanoparticles functionalized at the surface by at least one organic ligand L1 in stage (1) of the process according to the invention may be prepared via a process comprising at least the stages consisting in, indeed even a process consisting in the stages of:

(a1) having available at room temperature a precursor powder having the composition AgₓM_{y}M′_{z}(S₂CN(C₂H₅)₂)_{x+2y+3z}, with M, M′, x, y and z being as defined above;

(a2) dispersing at room temperature said precursor powder in the organic ligand L1 in the liquid state;

(a3) subjecting the dispersion obtained in stage (a2) to a heat treatment, under an inert atmosphere, for example under an argon atmosphere, at a temperature of between 100° C. and 250° C. to obtain said nanocrystals having the composition (I);

(a4) optionally forming at the surface of the nanocrystals obtained on conclusion of stage (a3) a coating of semiconductor compound; and

(a5) recovering the nanoparticles formed of a nanocrystal having the composition (I) and functionalized at the surface by the organic ligand L1 which are obtained on conclusion of stage (a3), or the nanoparticles having a core/shell structure, with the core formed of the nanocrystal having the composition (I) and the shell made of semiconductor, said nanoparticles being functionalized at the surface by said organic ligand L1, obtained on conclusion of stage (a4).

As mentioned above, said process does not include any pre-heat treatment stage before the heat treatment performed in stage (a3) on the dispersion of said precursor in the organic ligand L1.

Stage (a4) comprises more particularly the stages of adding to the dispersion of nanocrystals obtained on conclusion of stage (a3), at least one precursor of the element or elements from Group I, II or III and at least one precursor of the element or elements from Group V or VI; and subjecting the dispersion thus formed to a heat treatment favorable to the formation of a coating of semiconductor compound at the surface of the nanocrystals.

Stage (2): Exchange of Ligands by a Phosphine Ligand

In a second stage of the process of the invention, an exchange is carried out, at least in part, of the organic ligands L1, for example of amine type, by ligands of phosphine type, denoted L2 in the continuation of the text, of general formula:

PR₃ (II), or its oxidized form O═PR₃ (II′),

the R groups, which are identical or different, representing hydrogen, an alkyl group or a cycloalkyl group, said alkyl or cycloalkyl groups optionally being substituted.

In the context of the invention:
alkyl is understood to mean a saturated and linear or branched aliphatic group, in particular exhibiting from 1 to 20 carbon atoms, preferably from 2 to 10 carbon atoms; and
cycloalkyl is understood to mean a cyclic alkyl group, in particular exhibiting from 3 to 7 carbon atoms, preferably a hexyl group.

The alkyl and cycloalkyl groups may optionally be substituted.

By way of example, they may be substituted by one or more —COOH groups.

Other substitutions may be envisaged, in particular for introducing an additional functionality, for example by one or more groups chosen from a halogen atom, —Si(OR¹)₃ with R¹ representing a hydrogen atom or an alkyl group, —SH, —OCN, or also for increasing the electron-donating effect of the R groups on the phosphorus atom, for example by one or more groups chosen from —OR², —N(R³)₂, —NHCOR⁴ or —CH═C(R⁵)₂, it being possible for the R², R³, R⁴ and R⁵ groups to be chosen, independently of one another, from hydrogen and an alkyl group.

The ligands L2 of phosphine type according to the invention may more particularly be chosen from the following compounds:

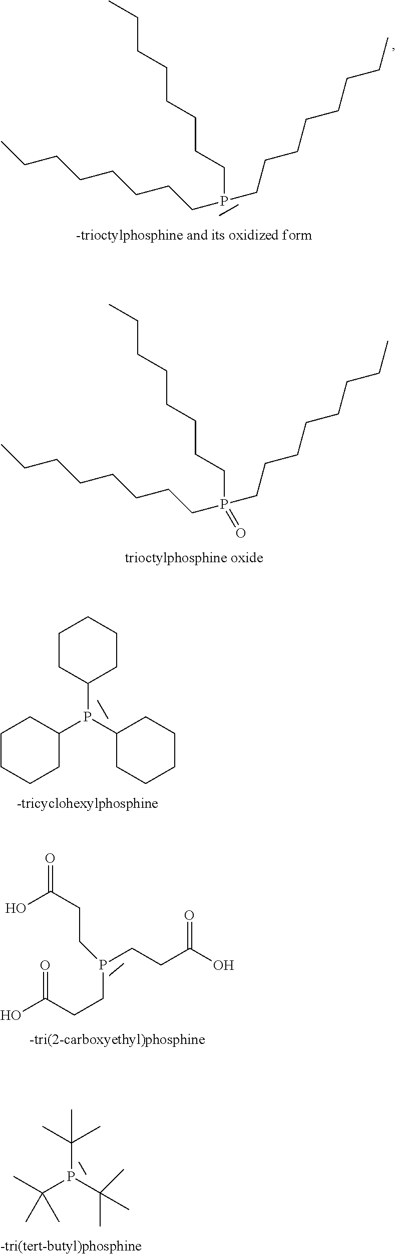

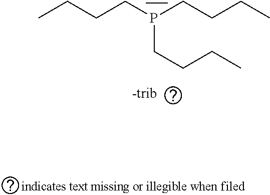

Preferably, phosphines having a low stearic hindrance and having one or more R groups exhibiting a high electron-donating inductive effect are favored according to the invention.

According to a particularly preferred embodiment, the phosphine ligand L2 is chosen from tri(2-carboxyethyl)phosphine, tri(tert-butyl)phosphine, trioctylphosphine and tributylphosphine.

Preferably, the phosphine ligand L2 is trioctylphosphine or tributylphosphine.

According to an alternative embodiment, the phosphine ligand L2 is tributylphosphine.

According to another particularly preferred alternative embodiment, the phosphine ligand L2 is trioctylphosphine.

The exchange of the ligands in stage (2) of the process of the invention may be carried out via at least the stages consisting in:
dispersing the nanoparticles prepared in stage (1) in an organic solvent in which the ligand compound L2 of phosphine type is soluble;
adding, to said dispersion, said ligand compound L2 of phosphine type, preferably at ambient temperature; and
leaving said nanoparticles and said ligand compound L2 of phosphine type in contact, preferably with stirring, for a period of time sufficient to carry out, at the surface of the nanoparticles, an at least partial exchange of the organic ligands L1, for example oleylamine, by said ligands L2 of phosphine type.

The organic solvent for dispersing nanoparticles may more particularly be chloroform.

The exchange of the ligands may be carried out in a few minutes, in order to result in the nanoparticles according to the invention functionalized at the surface by the specific ligands L2 of phosphine type.

A person skilled in the art is in a position to adjust the amount of ligand L2 of phosphine type to be added to the dispersion of nanoparticles and the duration of the contacting operation, in particular from the viewpoint of the nature of the ligand L2 of phosphine type employed, in order to obtain the desired exchange of ligands.

According to another of its aspects, the invention is also targeted at nanoparticles formed in all or part of a nanocrystal, the chemical composition of which corresponds to the formula AgₓM_{y}M′_{z}S_{0.5x+y+1.5z} (I), in which M, M′, x, y and z are as defined above, and functionalized at the surface by a ligand of phosphine L2 type of general formula PR₃ (II) or its oxidized form O═PR₃ (II′), R being as defined above.

In particular, nanoparticles formed in all or part of a ZAIS nanocrystal and functionalized at the surface by a ligand of phosphine L2 type are concerned.

The nanoparticles may more particularly be obtained according to the process described above.

In particular, the nanocrystal having the composition (I), for example the ZAIS nanocrystal, of the nanoparticles according to the invention is preferably prepared according to the novel process described above.

The nanoparticles functionalized at the surface by said ligands L2 of phosphine type may exhibit a mean size of between 3 and 40 nm, in particular between 5 and 10 nm.

The mean size of the nanoparticles according to the invention may be determined by electron microscopy, in particular by transmission electron microscopy and more particularly by high resolution transmission electron microscopy (HRTEM) or scanning transmission electron microscopy (STEM).

According to a specific embodiment, the nanoparticles according to the invention are provided in the form of a colloidal solution. Such a colloidal solution may be obtained by suspension of said nanoparticles in an organic solvent, in particular chloroform.

The nanoparticles according to the invention, in particular the ZAIS-based nanoparticles, exhibit, under excitation in the spectral range, an emission maximum in the range of wavelengths of between 550 nm and 850 nm which varies according to the composition of the nanocrystal and more particularly the composition of the precursor employed for its preparation. They advantageously exhibit a broad emission band (from 100 to 150 nm).

Applications

As touched on above, the nanoparticles according to the invention may be employed as photoluminescent material for various applications, for example as marker in biology or in light-emitting devices, for example as luminophore in a light-emitting diode.

The invention thus relates, according to another of its aspects, to the use of the nanoparticles of the invention as marker in biology or the luminophore in a light-emitting diode.

According to a particularly advantageous alternative embodiment, the nanoparticles according to the invention are employed in order to form the luminophore of a white light-emitting diode.

The use of the nanoparticles according to the invention in devices of this type falls within the province of techniques known to a person skilled in the art.

According to yet another of its aspects, the present invention relates to a light-emitting device, in particular a light-emitting diode and more particularly a white light-emitting diode, containing a phosphor based on nanoparticles according to the invention.

Of course, the invention is not limited to the devices touched on above and other applications of the functionalized nanoparticles according to the invention may be envisaged.

The invention will now be described by means of following examples and figures given by way of illustration and without limitation of the invention.

### FIGURES

FIG. 1: Diagrammatic representation of the exchange of the oleylamine ligands by trioctylphosphine ligands at the surface of the ZAIS nanocrystals according to the process of the invention;

FIG. 2: Internal quantum efficiency obtained for the wavelength corresponding to the emission maximum for ZAIS nanocrystals, prepared from different precursor compositions according to the process described by Torimoto et al. [1], without exchange of ligands (-▪-) and after exchange of the oleylamine ligands by trioctylphosphine ligands (--);

FIG. 3: Internal quantum efficiency obtained for the wavelength corresponding to the emission maximum for ZAIS nanocrystals prepared from different precursor compositions according to the novel process of example 2, without exchange of ligands (-▪-) and after exchange of the oleylamine ligands by trioctylphosphine ligands according to the invention (--).

### EXAMPLES

### Example 1

### Synthesis of the Precursor AgₓZn_{y}In_{z}(S₂CN(C₂H₅)₂)_{x+2y+3z} Powder

A precursor (AgIn)ₙZn₂₍₁₋ₙ₎(S₂CN(C₂H₅)₂)₄ powder is prepared as follows.

n moles of AgNO₃, n moles of In(NO₃)₃ and 2-2n moles of Zn(NO₃)₂ are dissolved in 250 ml of DI water (solution S1). The total amount of positive charges originating from the Ag⁺, In³⁺ and Zn²⁺ ions introduced is set at 12.5 mmol. 5.6328 g (25 mmol) of sodium diethyldithiocarbamate are dissolved on their own in 250 ml of DI water (solution S2). Once the two solutions are thoroughly homogeneous, the solution S1 is slowly added to the solution S2 with stirring. A pale yellow precipitate is immediately formed. The solution is then left stirring for at least three days. The color of the precipitate gradually changes from pale yellow to blue.

The precipitate is recovered by centrifuging the solution and then washed three times with 250 ml of DI water and once with 50 ml of methanol. The precipitate is subsequently dried in the open air before use.

### Example 2

### Synthesis of the ZAIS Nanocrystals

300 mg of precursor prepared as described in example 1 are dispersed in 9 ml of predistilled oleylamine. The solution is subsequently introduced into a round-bottomed glass flask with stirring under argon. After degassing the solution under argon at ambient temperature for 15 minutes, the round-bottomed flask is introduced into a heating bath at a temperature of 180° C. The solution then very rapidly becomes dark and is left stirring under argon for 20 minutes. After these 20 minutes, the solution is quickly cooled to ambient temperature and then placed in tubes in order to carry out its purification.

The crude synthesis product contains ZAIS nanocrystals (tetragonal) and also larger particles of orthorhombic AgₓZn_{y}In_{z}S_{0.5x+y+1.5z} and Ag₂S dispersed in the oleylamine. The solution is centrifuged twice in order to recover only the nanometric ZAIS particles, which have remained in suspension. The oleylamine solution containing the nanocrystals is then clear.

This solution is subsequently introduced into 35 ml of methanol in order to flocculate the nanocrystals. The mixture is centrifuged in order to recover only the flocculated nanocrystals, which have fallen to the bottom, while the excess oleylamine is removed with the supernatant. Approximately 5 ml of chloroform are added to the nanocrystals in order to disperse them. The solution obtained is then clear, indicating good colloidal stability of the nanocrystals in the chloroform.

### Example 3

### Synthesis of the Core (ZAIS Nanocrystal)/Shell (ZnS) Nanoparticles

300 mg of precursor prepared as described in example 1 are dispersed in 9 ml of predistilled oleylamine. The solution is subsequently introduced into a round-bottomed glass flask with stirring under argon. After degassing the solution under argon at ambient temperature for 15 minutes, the round-bottomed flask is introduced into a heating bath at a temperature of 180° C. The solution then very rapidly becomes black and is left stirring under argon for 20 minutes under these conditions. After these 20 minutes, the solution is quickly cooled to ambient temperature and then placed in tubes in order to carry out its purification.

In order to remove the undesired particles, the solution is centrifuged twice in order to recover only the nanometric particles, which have remained in suspension. The oleylamine solution containing the nanocrystals is then clear. This solution is subsequently introduced into a fresh round-bottomed glass flask, with stirring and under argon.

On their own, 70 mg of zinc acetate and 30 mg of thioacetamide are dissolved separately in 2.5 ml of distilled oleylamine. After complete dilution, the two solutions are mixed (solution S3). After degassing the solution of nanocrystals (15 minutes under argon), the round-bottomed flask is introduced into a heating bath at 140° C. One minute after the beginning of the heating, the solution S3 is added dropwise to the round-bottomed flask. Addition is carried out in 2 minutes and the reaction is left at 140° C. for a further additional 2 minutes (total heating time: 5 minutes). The solution is subsequently rapidly cooled to ambient temperature before removing the excess oleylamine and dispersing the nanocrystals.

For this, the solution is subsequently introduced into 35 ml of methanol in order to flocculate the nanocrystals. The mixture is centrifuged in order to recover only the flocculated nanocrystals, which have fallen to the bottom, while the excess oleylamine is removed with the supernatant. Approximately 5 ml of chloroform are added to the nanocrystals in order to disperse them.

### Example 4

### Exchange of Ligand with a Derivative of Phosphine Type

Once the solution of ZAIS nanocrystals or of core (ZAIS nanocrystal)/shell (ZnS) nanoparticles has been obtained in chloroform, as described in examples 2 and 3, a few drops (100 μL) of trioctylphosphine or of another derivative of phosphine type are added to the solution. The solution is subsequently stirred.

Photoluminescence measurements are carried out using an absolute quantum yield spectrometer (Hamamatsu Quantaurus—QY C11347).

An increase in the photoluminescence of the nanoparticles under UV excitation is very rapidly observed (in less than one minute).

### Example 5

### Increase in the Quantum Efficiency by the Functionalization by a Ligand Compound of Phosphine Type

Effect of the Surface Modification by Trioctylphosphine of ZAIS Nanocrystals Synthesized According to Torimoto et al. [1] and According to the Process of Example 2

The effect of the surface functionalization of the nanocrystals by trioctylphosphine ligands on the internal quantum efficiency was evaluated, on the one hand for nanocrystals prepared according to the process described by Torimoto et al. [1] and, on the other hand, for nanocrystals prepared according to the novel process described in example 2, for different compositions of (AgIn)ₙZn₂₍₁₋ₙ₎(S₂CN(C₂H₅)₂)₄ precursor used.

The photoluminescence internal quantum efficiencies were determined with the absolute quantum yield spectrometer (Hamamatsu Quantaurus—QY C11347) comprising a custom-made integrating sphere.

For each nanocrystal, the internal quantum efficiency (%) is evaluated for the wavelength corresponding to the emission maximum of the nanocrystal.

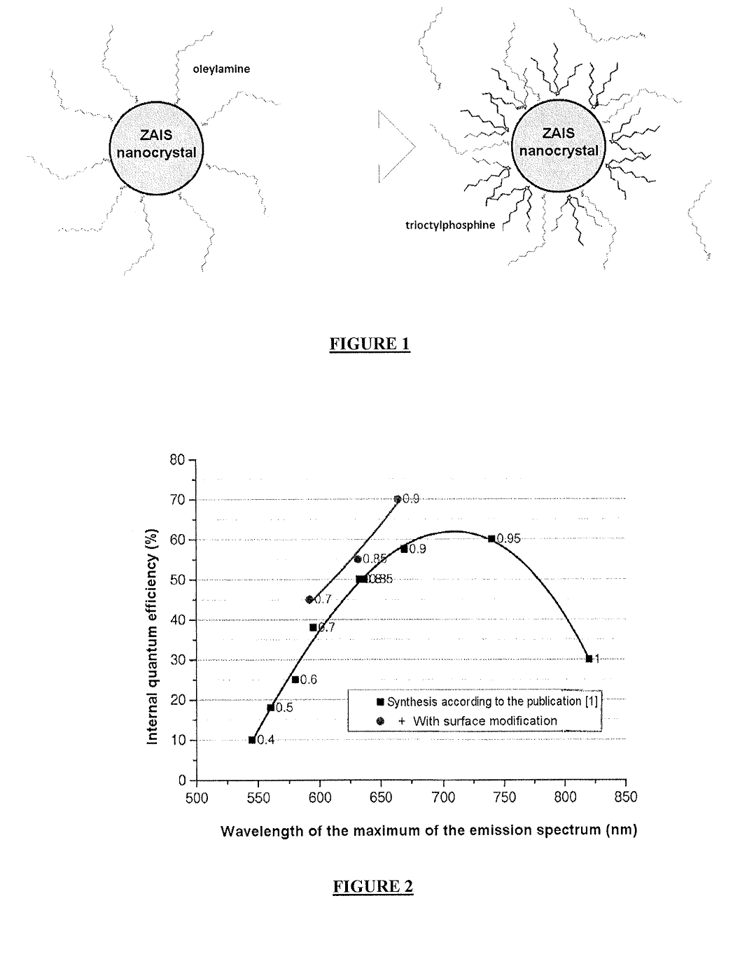

FIG. 2 represents the internal quantum efficiency data obtained for the wavelength of the photoluminescence peak obtained for each nanocrystal prepared according to the process described by Torimoto et al. [1], without exchange of ligands (-▪-) and after exchange of the oleylamine ligands by trioctylphosphine ligands (--). (The surface treatment by trioctylphosphine was applied only for some nanocrystals synthesized with the process described by Torimoto et al. [1].)

The exchange of ligands was carried out as described in example 4 starting from ZAIS nanocrystals obtained according to the process described by Torimoto et al. [1].

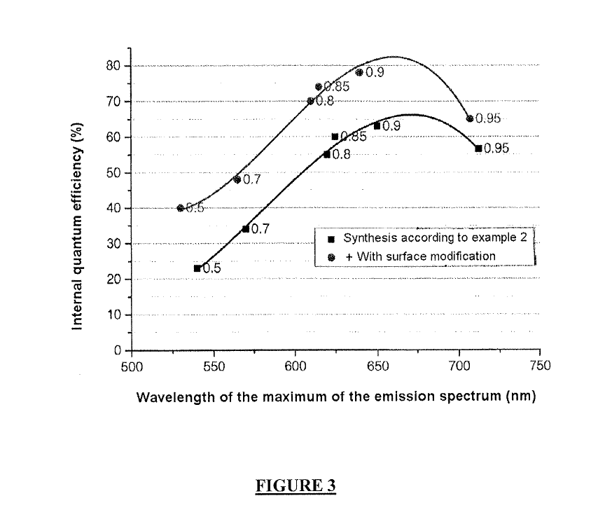

Likewise, FIG. 3 represents the quantum efficiency data obtained for the wavelength of the photoluminescence peak obtained for each nanocrystal prepared according to the novel process of example 2, without exchange of ligands (-▪-) and after exchange of the oleylamine ligands by trioctylphosphine ligands in accordance with example 4 (--).

The labels (“0.4”, “0.5”, and the like) appearing in the graphs specify the “n” datum of the composition of the precursor used for the synthesis of the ZAIS nanocrystal.

It emerges from FIGS. 2 and 3 that the functionalization of the ZAIS nanocrystals by the ligand of phosphine type (trioctylphosphine) makes it possible to improve the photoluminescence internal quantum efficiency of the ZAIS nanocrystal, whatever their method of preparation.

Advantageously, this improvement in the IQE is intensified in the case of the nanocrystals prepared according to the novel process of example 2, in comparison with those obtained according to the synthesis protocol known from the publication [1].

Effect of the Surface Modification by Different Ligands of Phosphine Type

The following table 1 combines the IQE (total efficiency obtained over the whole of the emission spectrum for an excitation wavelength of 510 nm) values obtained after exchange of the oleylamine ligands of ZAIS nanocrystals synthesized according to example 2 (n of the precursor composition having the value 0.7) with the derivatives of phosphine type listed in table 1, in accordance with example 4.

The value of the increase in IQE, with respect to the reference IQE value obtained with surface functionalization by oleylamine, is shown in brackets.

TABLE 1

| Functionalization ligands | IQE (%) |
|---|---|
| Oleylamine (end of synthesis, | 41 |
| reference) | |
| Orthophosphoric acid (not in | 31 (−10) |
| accordance) | |
| Triphenylphosphine (not in | 32 (−9) |
| accordance) | |
| Tricyclohexylphosphine | 44 (+3) |
| Tri(2-carboxyethyl)phosphine | 49 (+8) |
| Tri(tert-butyl)phosphine | 52 (+11) |
| Trioctylphosphine | 54 (+13) |
| Tributylphosphine | 60 (+19) |

It should be noted that the values obtained are different but the change in the IQE values with the different functionalization ligands remains identical for other excitation wavelengths and in particular at a wavelength of 450 nm.

The results obtained show that the nanocrystals functionalized with ligands of phosphine type in accordance with the invention make it possible to improve the IQE of ZAIS nanocrystals.

### REFERENCES

[1] Torimoto et al., Facile Synthesis of ZnS—AgInS₂ Solide Solution Nanoparticles for a Color-Adjustable Luminophore, J. Am. Chem. Soc., 129, 12388-12389 (2007);
[2] WO 2013/162334;
[3] KR 2013-0095603;
[4] Torimoto et al., Remarkable photoluminescence enhancement of ZnS—AgInS₂ solid solution nanoparticles by post-synthesis treatment, Chem. Commun., 46, 2082 (2010);
[5] Mao et al., Study of the Partial Ag-to-Zn Cation Exchange in AgInS₂/ZnS Nanocrystals, J. Phys. Chem., C117, 648-656 (2013);
[6] Krause et al., Chemical and Thermodynamic Control of the Surface of Semiconductor Nanocrystals for Designer White Light Emitters, ACS Nano, 7, 5922-5929 (2013).

1. Process for increasing the photoluminescence internal quantum efficiency of nanoparticles formed at least partly of a nanocrystal of AgₓM_{y}M′_{z}S_{0.5x+y+1.5z} type, comprising at least the stages consisting in:
(1) having available nanoparticles formed in all or part of a nanocrystal, the chemical composition of which corresponds to the formula (I):
AgₓM_{y}M′_{z}S_{0.5x+y+1.5z} (I)
in which:
M is chosen from zinc, cadmium, mercury and their mixtures;
M′ is chosen from aluminum, gallium, indium, thallium and their mixtures; and
0<x≦1, 0≦y≦1 and 0<z≦1;
said nanoparticles being functionalized at the surface by at least one organic ligand L1 different from a ligand of phosphine type;
wherein the nanocrystals having the chemical composition of formula (I) are prepared beforehand via a process comprising at least the stages consisting in:
(a) having available a precursor powder having the composition AgₓM_{y}M′_{z}(S₂CN(C₂H₅)₂)_{x+2y+3z}, with M, M′, x, y and z being as defined above;
(b) dispersing said precursor powder in the organic ligand L1 in the liquid state; and
(c) subjecting the dispersion obtained in stage (b) to a heat treatment, under an inert atmosphere, at a temperature of between 100° C. and 250° C., to obtain said nanocrystals having the chemical composition of formula (I);
said process for the preparation of the nanocrystals employing only a single stage of heat treatment consisting in stage (c); and
(2) bringing together said nanoparticles and at least one ligand compound L2 of phosphine type of general formula:
PR₃ (II), or its oxidized form O═PR₃ (II′),
each of the R groups, which are identical or different, being chosen from hydrogen, an alkyl group and a cycloalkyl group, said alkyl and cycloalkyl groups optionally being substituted;
under conditions favorable to an exchange, at least in part, of the organic ligands L1 by said ligands of phosphine type L2.

2. Process according to claim 1, in which the nanoparticles are formed in all or part of a nanocrystal, the chemical composition of which corresponds to the formula (I) in which M represents zinc and M′ represents indium.

3. Process according to claim 1, in which the nanoparticles in stage (1) are formed in all or part of a nanocrystal composed of a solid solution of AgₓZn_{y}In_{z}S_{0.5x+y+1.5z} (I′) type in which x, y and z vary between 0 and 1, x, y and z all being different from zero.

4. Process according to claim 1, in which the organic ligand L1 for functionalization of the nanoparticles in stage (1) is chosen from amines comprising at least one saturated or unsaturated and linear or branched hydrocarbon chain comprising at least 8 carbon atoms.

5. Process according to claim 1, in which the organic ligand L1 for functionalization of the nanoparticles in stage (1) is oleylamine.

6. Process according to claim 1, in which the heat treatment in stage (c) is carried out at a temperature of approximately 180° C.

7. Process according to claim 1, in which the heat treatment in stage (c) is carried out for a period of time ranging from 3 minutes to 4 hours.

8. Process according to claim 1, in which the nanoparticles are nanocrystals, the chemical composition of which corresponds to the formula (I)
AgₓM_{y}M′_{z}S_{0.5x+y+1.5z} (I)
in which:
M is chosen from zinc, cadmium, mercury and their mixtures;
M′ is chosen from aluminum, gallium, indium, thallium and their mixtures; and
0<x≦1, 0≦y≦1 and 0<z≦1.

9. Process according to claim 1, in which the nanoparticles exhibit a structure of core/shell type, the core being a nanocrystal having the composition AgₓM_{y}M′_{z}S_{0.5x+y+1.5z} (I) in which:
M is chosen from zinc, cadmium, mercury and their mixtures;
M′ is chosen from aluminum, gallium, indium, thallium and their mixtures;
0<x≦1, 0≦y≦1 and 0<z≦1; and
the shell being composed of a semiconductor compound.

10. Process according to claim 9, in which the semiconductor compound is chosen from binary, ternary or quaternary semiconductor alloys formed of one or more element(s) from Group I, II or III and of one or more element(s) from Group V or VI.

11. Process according to claim 9, in which the semiconductor compound is chosen from ZnS, ZnSe, CdS, AlP, GaP, Al₂S₃ and Ga₂S₃.

12. Process according to claim 9, in which the shell of said nanoparticles is made of ZnS.

13. Process according to claim 9, in which the nanoparticles having a core/shell structure in stage (1) are prepared via at least the stages consisting in:
(i) having available nanocrystals having the chemical composition of formula (I), dispersed in the organic ligand L1 in the liquid state, said dispersion being obtained on conclusion of stage (c);
(ii) adding, to said dispersion of nanocrystals, at least one precursor of the element or elements from Group I, II or III and at least one precursor of the element or elements from Group V or VI;
(iii) subjecting the dispersion thus formed to a heat treatment favorable to the formation of a coating of semiconductor compound, at the surface of the nanocrystals; and
(iv) recovering the nanoparticles having a core/shell structure which are functionalized at the surface by said organic ligand L1.

14. Process according to claim 13 for the preparation of nanoparticles of core/shell structure, the shell being made of ZnS, in which the dispersion of nanocrystals is supplemented in stage (ii) with zinc acetate and thioacetamide.

15. Process according to claim 1, in which the ligand L2 of phosphine type in stage (2) is chosen from trioctylphosphine, trioctylphosphine oxide, tricyclohexylphosphine, tri(2-carboxyethyl)phosphine, tri(tert-butyl)phosphine and tributylphosphine.

16. Process according to claim 1, in which the ligand L2 of phosphine type in stage (2) is chosen from trioctylphosphine and tributylphosphine.

17. Process according to claim 1, in which the ligand L2 of phosphine type in stage (2) is trioctylphosphine.

18. Process according to claim 1, in which stage (2) of exchange of the ligands is carried out via at least the stages consisting in:
dispersing the nanoparticles of stage (1) in an organic solvent in which the ligand compound L2 of phosphine type is soluble;
adding, to said dispersion, said ligand compound L2 of phosphine type; and
leaving said nanoparticles and said ligand compound L2 of phosphine type in contact, for a period of time sufficient to carry out, at the surface of the nanoparticles, an at least partial exchange of the organic ligands L1, by said ligands L2 of phosphine type.

19. Nanoparticles formed in all or part of a nanocrystal, the chemical composition of which corresponds to the formula:
AgₓM_{y}M′_{z}S_{0.5x+y+1.5z} (I)
in which
M is chosen from zinc, cadmium, mercury and their mixtures;
M′ is chosen from aluminum, gallium, indium, thallium and their mixtures; and
0<x≦1, 0≦y≦1 and 0<z≦1;
said nanoparticles being functionalized at the surface by a ligand L2 of phosphine type of general formula:
PR₃ (II), or its oxidized form O═PR₃ (II′),
each of the R groups, which are identical or different, being chosen from hydrogen, an alkyl group and a cycloalkyl group, said alkyl and cycloalkyl groups optionally being substituted;
said nanoparticles being obtained according to the process comprising at least the stages consisting in:
(1) having available nanoparticles formed in all or part of a nanocrystal, the chemical composition of which corresponds to the formula (I):
AgₓM_{y}M′_{z}S_{0.5x+y+1.5z} (I)
in which M, M′, x, y and z are as defined above;
said nanoparticles being functionalized at the surface by at least one organic ligand L1 different from a ligand of phosphine type;
wherein the nanocrystals having the chemical composition of formula (I) are prepared beforehand via a process comprising at least the stages consisting in:
(a) having available a precursor powder having the composition AgₓM_{y}M′_{z}(S₂CN(C₂H₅)₂)_{x+2y+3z}, with M, M′, x, y and z being as defined above;
(b) dispersing said precursor powder in the organic ligand L1 in the liquid state; and
(c) subjecting the dispersion obtained in stage (b) to a heat treatment, under an inert atmosphere, at a temperature of between 100° C. and 250° C., to obtain said nanocrystals having the chemical composition of formula (I);
said process for the preparation of the nanocrystals employing only a single stage of heat treatment consisting in stage (c); and
(2) bringing together said nanoparticles and at least one ligand compound L2 of phosphine type of general formula PR₃ (II), or its oxidized form O═PR₃ (II′), each of the R groups, which are identical or different, being as defined above, under conditions favorable to an exchange, at least in part, of the organic ligands L1 by said ligands of phosphine type L2.

20. Process for the preparation of a marker in biology or a luminophore in a light-emitting diode, using nanoparticles formed in all or part of a nanocrystal, the chemical composition of which corresponds to the formula:
AgₓM_{y}M′_{z}S_{0.5x+y+1.5z} (I)
in which
M is chosen from zinc, cadmium, mercury and their mixtures;
M′ is chosen from aluminum, gallium, indium, thallium and their mixtures; and
0<x≦1, 0≦y≦1 and 0<z≦1;
said nanoparticles being functionalized at the surface by a ligand L2 of phosphine type of general formula:
PR₃ (II), or its oxidized form O═PR₃ (II′),
each of the R groups, which are identical or different, being chosen from hydrogen, an alkyl group and a cycloalkyl group, said alkyl and cycloalkyl groups optionally being substituted;
said nanoparticles being obtained according to the process comprising at least the stages consisting in:
(1) having available nanoparticles formed in all or part of a nanocrystal, the chemical composition of which corresponds to the formula (I):
AgₓM_{y}M′_{z}S_{0.5x+y+1.5z} (I)
in which M, M′, x, y and z are as defined above;
said nanoparticles being functionalized at the surface by at least one organic ligand L1 different from a ligand of phosphine type;
wherein the nanocrystals having the chemical composition of formula (I) are prepared beforehand via a process comprising at least the stages consisting in:
(a) having available a precursor powder having the composition AgₓM_{y}M′_{z}(S₂CN(C₂H₅)₂)_{x+2y+3z}, with M, M′, x, y and z being as defined above;
(b) dispersing said precursor powder in the organic ligand L1 in the liquid state; and
(c) subjecting the dispersion obtained in stage (b) to a heat treatment, under an inert atmosphere, at a temperature of between 100° C. and 250° C., to obtain said nanocrystals having the chemical composition of formula (I);
said process for the preparation of the nanocrystals employing only a single stage of heat treatment consisting in stage (c); and
(2) bringing together said nanoparticles and at least one ligand compound L2 of phosphine type of general formula PR₃ (II), or its oxidized form O═PR₃ (II′), each of the R groups, which are identical or different, being as defined above, under conditions favorable to an exchange, at least in part, of the organic ligands L1 by said ligands of phosphine type L2.

21. The process according to claim 20 for the preparation of a luminophore of a white light-emitting diode.

22. Light-emitting device containing a phosphor based on nanoparticles formed in all or part of a nanocrystal, the chemical composition of which corresponds to the formula:
AgₓM_{y}M′_{z}S_{0.5x+y+1.5z} (I)
in which
M is chosen from zinc, cadmium, mercury and their mixtures;
M′ is chosen from aluminum, gallium, indium, thallium and their mixtures;
0<x≦1, 0≦y≦1 and 0<z≦1;
said nanoparticles being functionalized at the surface by a ligand L2 of phosphine type of general formula:
PR₃ (II), or its oxidized form O═PR₃ (II′),
each of the R groups, which are identical or different, being chosen from hydrogen, an alkyl group and a cycloalkyl group, said alkyl and cycloalkyl groups optionally being substituted;
said nanoparticles being obtained according to the process comprising at least the stages consisting in:
(1) having available nanoparticles formed in all or part of a nanocrystal, the chemical composition of which corresponds to the formula (I):
AgₓM_{y}M′_{z}S_{0.5x+y+1.5z} (I)
in which M, M′, x, y and z are as defined above;
said nanoparticles being functionalized at the surface by at least one organic ligand L1 different from a ligand of phosphine type;
wherein the nanocrystals having the chemical composition of formula (I) are prepared beforehand via a process comprising at least the stages consisting in:
(a) having available a precursor powder having the composition AgₓM_{y}M′_{z}(S₂CN(C₂H₅)₂)_{x+2y+3z}, with M, M′, x, y and z being as defined above;
(b) dispersing said precursor powder in the organic ligand L1 in the liquid state; and
(c) subjecting the dispersion obtained in stage (b) to a heat treatment, under an inert atmosphere, at a temperature of between 100° C. and 250° C., to obtain said nanocrystals having the chemical composition of formula (I);
said process for the preparation of the nanocrystals employing only a single stage of heat treatment consisting in stage (c); and
(2) bringing together said nanoparticles and at least one ligand compound L2 of phosphine type of general formula PR₃ (II), or its oxidized form O═PR₃ (II′), each of the R groups, which are identical or different, being as defined above, under conditions favorable to an exchange, at least in part, of the organic ligands L1 by said ligands of phosphine type L2.

23. The light-emitting device according to claim 22, said device being a white light-emitting diode.
